(19) United States
(12) Patent Application Publication
(10) Pub. No.: US 2009/0180268 A1
(43) Pub. Date: Jul. 16, 2009

(54) NOTEBOOK COMPUTER AND FOOTPAD THEREOF

(75) Inventor: Xian-huang Guo, Kunshan City (TW)

Correspondence Address: AUSTIN RAPP & HARDMAN, 170 South Main Street, Suite 735, SALT LAKE CITY, UT, 84101, US

(73) Assignee: Kunshan Yurong Electronics Co., Ltd., Kunshan City (TW)

(21) Appl. No.: 12/136,526

(22) Filed: Jun. 10, 2008

(30) Foreign Application Priority Data
Jan. 15, 2008 (CN) 200820054714.0

(51) Int. Cl. H05K 7/00

(52) U.S. Cl. 361/810

(57) ABSTRACT

A notebook computer includes a plurality of securing holes formed on a bottom surface thereof and a plurality of footpads mounted to the bottom surface of the notebook computer through the securing holes. Each footpad includes an inner element and an outer element, and the outer element is moulded on the inner element and has a large friction coefficient. The inner element has at least one securing post formed on a top surface thereof for respectively insertion into the securing hole of the notebook computer. The footpad is formed by an integrated injection moulding process in which the inner element is first moulded, and then the outer element is moulded on the inner element. The moulding efficiency is improved. Further, the footpad features anti-slipping due to the large friction coefficient of the outer element.

### BACKGROUND OF THE INVENTION

1. Field of the Invention

The present invention relates to a notebook computer and a footpad thereof, and particularly to a footpad of a notebook computer having anti-slip features.

2. Description of Prior Art

A notebook computer has an enclosure often made of a hard material, such as engineering plastic or Al—Mg alloy, and the bottom of the notebook computer enclosure made of such a hard material is smooth. When the notebook computer in use is put on a desk top, it is hard to dissipate the heat generated by the notebook computer from the bottom of the notebook computer. Also, the friction force between the bottom surface of the notebook computer and the desk top is small so that the notebook computer may slip out of the desk top, drop on the ground and, thus get damaged due to an accidental hit or collision.

Referring to FIGS. 1A and 1B, a plurality of footpads 91, all of which are solid objects made of rubber material, are mounted on the bottom surface 90 of the notebook computer 9 by adhesive layers 92 to overcome the above-discussed problems of heat dissipation and accidental slipping. In detailed words, when the notebook computer 9 is put on the desktop, a space is formed between the bottom surface 90 of the notebook computer 9 and the desktop to help heat dissipation; and the notebook computer 9 can securely stay on the desktop due to the significant friction coefficient of the rubber material, leading to a large friction force between the footpad 91 and the desktop.

Since the frequent change of the surrounding environments, including temperature and humidity, can affect and even reduce the adhesion force of the adhesive layer 92. When the adhesion between the footpad 91 and the bottom surface 90 of the notebook computer 9 deteriorates, the footpad 91 may get unexpectedly off the bottom surface 90 so that the notebook computer 9 cannot be properly positioned. Moreover, the footpad 91 may be separated from the bottom surface 90 in the events of accidental collision with other objects during the use of the notebook computer 9. Consequently, solely depending on the adhesion layer 92 to solve the slipping problem is generally impractical.

Referring to FIG. 1C, in other known techniques, to prevent a footpad 91 from undesirably separating from a notebook computer 8, an annular protruding support 81 is formed on a bottom surface 80 of the notebook computer 8 and a blind hole (not labeled) is defined in the support 81. The footpad 91, which is cylindrical in shape, is embedded in the blind hole of the annular protruding support 81 and adhered to an inner top surface of the blind hole by an adhesive layer 92. Though the annular protruding support 81 can protect the footpad 91 against collision, the connection reliability of the footpad 91 and the inner top surface of the blind hole is still primarily determined by the adhesion force of the adhesive layer 92. The footpad 91 is sure to separate from the notebook computer 8 when the adhesion force of the adhesive layer 92 deteriorates.

Hence, it is desired to have a computer enclosure footpad that overcomes the disadvantages as described above.

### SUMMARY OF THE INVENTION

Accordingly, an object of the present invention is to provide a footpad that is made up of inner and outer elements of different moldable materials having different friction coefficients and that is securely mountable to a bottom surface of a notebook computer to provide extended lifespan thereof and improved operational safety of the notebook computer and also realizing enhanced moulding efficiency of the footpad and reducing the moulding cost.

Another object of the present invention is to provide a notebook computer comprising a footpad having anti-slipping feature to improve the operational safety of the notebook computer.

To achieve the first object of the present invention, a footpad in accordance with the present invention is mounted on a bottom surface of a notebook computer. The footpad comprises an inner element made of a hot-melt material and an outer element made of a material having a large friction coefficient. The inner element has at least one securing post formed on a top surface thereof to be inserted into one securing hole formed on the bottom surface of the notebook computer. The outer element is integrally molded with the inner element and at least includes a bottom plate on a top surface of which the inner element is located.

To achieve the second object of the present invention, a notebook computer in accordance with the present invention includes a plurality of securing holes formed on a bottom surface of the notebook computer, and a plurality of footpads correspondingly cooperated with the securing holes and mounted on the bottom surface of the notebook computer. Each of the footpads includes an inner element made of a hot-melt material and an outer element made of a material having a large friction coefficient. The inner element has at least one securing post formed on a top surface thereof to be inserted into the corresponding securing hole formed on the bottom surface of the notebook computer. The outer element is integrally molded with the inner element and at least includes a bottom plate on a top surface of which the inner element is located.

In comparison with the prior art, the present footpad of the present invention has an anti-slip function by designing an outer element made of a material having a large friction coefficient. The present footpad has an anti-fall-off function by using an inner element made of a hot-melt material to be secured on the notebook computer. Consequently, the lifespan of the footpad is extended, and the operational safety and convenience of the notebook computer can be realized. Moreover, the footpad is formed by integrated injection molding so the molding efficiency of the footpad can be increased and the molding cost of the footpad can be decreased.

### BRIEF DESCRIPTION OF THE DRAWINGS

The present invention may best be understood through the following description with reference to the accompanying drawings, in which:

FIG. 1A is a cross-sectional schematic view showing a conventional footpad mounted to a bottom of a notebook computer;

FIG. 1B is a perspective view of the conventional footpad of FIG. 1A;

FIG. 1C is a cross-sectional schematic view showing another conventional footpad mounted to a bottom of a notebook computer;

FIG. 2 is a perspective view of a footpad constructed in accordance with an embodiment of the present invention;

FIG. 3 is a perspective view of an inner element of the footpad of the present invention;

FIG. 4 is a perspective view of an outer element of the footpad of the present invention;

FIG. 5 is another perspective view, taken from the bottom side, illustrating the outer element of the footpad of the present invention;

FIG. 6 is a perspective view of the footpad shown in FIG. 2 with an adhesive layer coated on a top surface thereof,

FIG. 7 is a cross-sectional schematic view, in an exploded form, illustrating the footpad of the present invention to be mounted to securing holes defined in a bottom of a notebook computer in accordance with the present invention;

FIG. 8 is a cross-sectional schematic view illustrating the footpad and notebook computer of FIG. 7 assembled together;

FIG. 9 is a cross-sectional schematic view illustrating that the footpad shown in FIG. 8 is processed by hot-melting to have a free top end thereof expanded, forming a mushroom-like head;

FIG. 10 is a cross-sectional schematic view, in an exploded form, illustrating a footpad constructed in accordance with another embodiment of the present invention to be mounted to securing holes defined in a bottom of a notebook computer in accordance with the present invention;

FIG. 11 is a cross-sectional schematic view illustrating the footpad and notebook computer of FIG. 10 assembled together;

FIG. 12 is a cross-sectional schematic view illustrating that the footpad shown in FIG. 11 is processed by hot-melting technology to have a free top end thereof forming a securing head embedded in a counter bore;

FIG. 13 is a cross-sectional view schematically illustrating a plastic injection molding assembly for forming a footpad according to the present invention;

FIG. 14 is a cross-sectional view schematically illustrating a rubber injection molding assembly for forming a footpad according to the present invention; and

FIG. 15 is a plan view schematically illustrating a rotation table of an injection molding machine for implementing the molding process in accordance with the present invention, showing two male molds of the respective plastic and rubber injection mold assemblies to be mounted thereon.

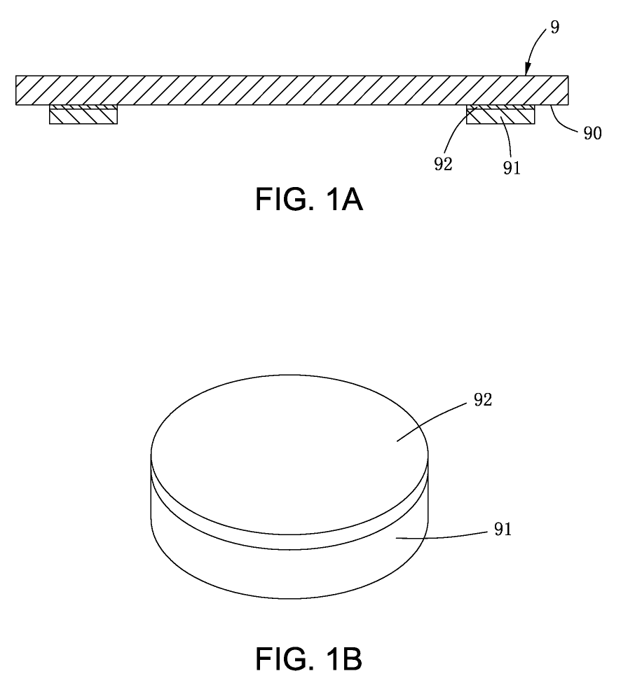

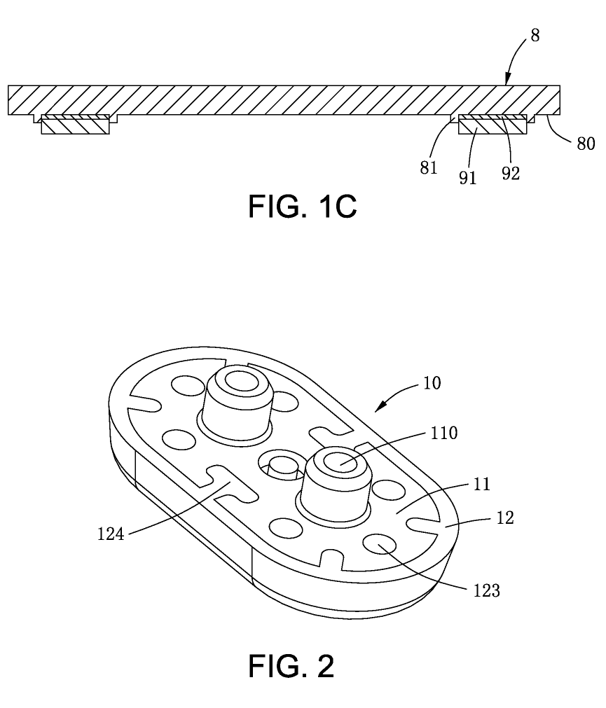

### DETAILED DESCRIPTION OF THE PREFERRED EMBODIMENTS

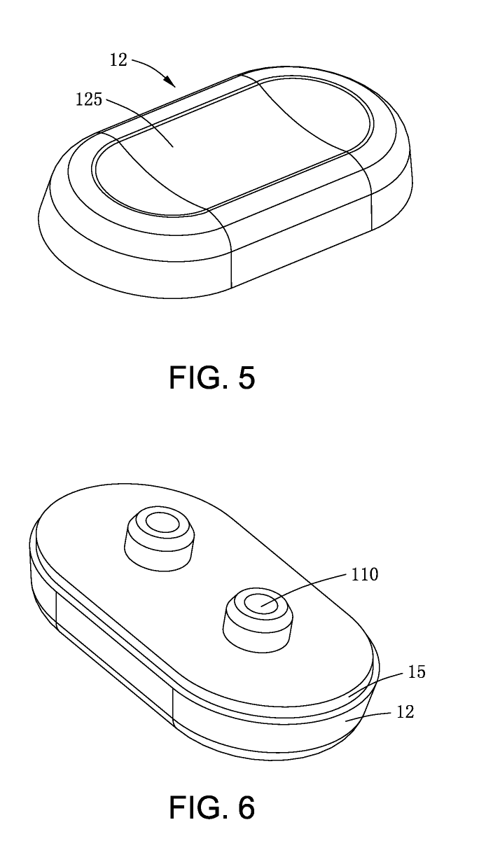

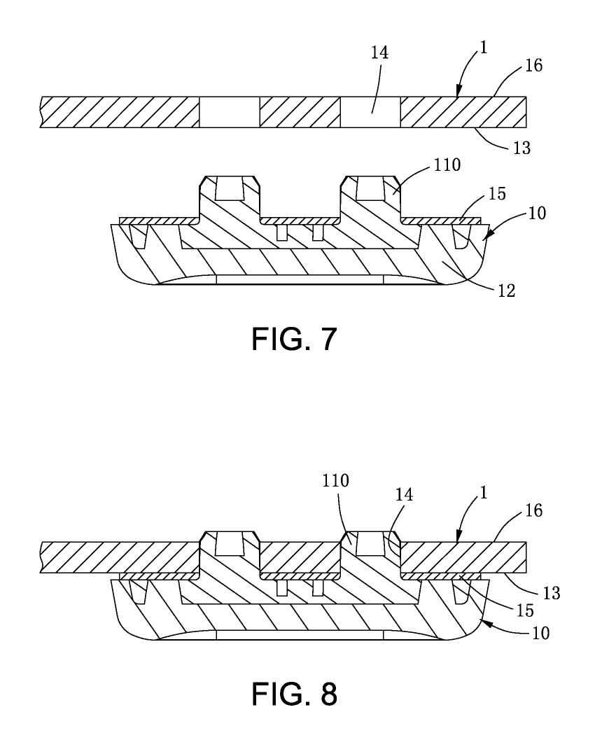

With reference to the drawings and in particular to FIGS. 2-5, a footpad constructed in accordance with an embodiment of the present invention, generally designated at 10, comprises an inner element 11 and an outer element 12. At least one securing post 110 is formed on a top surface of the inner element 11 for insertion into a securing hole 14 defined in a bottom surface 13 of a notebook computer 1, as best seen in FIG. 7. In the embodiment illustrated, the inner element 11 has two securing posts 110 formed on the top surface thereof. The inner element 11 is made of a hot-melting material, such as plastics. The outer element 12 is made of a material having a larger friction coefficient, such as rubber. The outer element 12 comprises a bottom plate 120, a circumferential enclosing wall 121 extending upward from a circumference of the bottom plate 120, and a receiving space 122 defined by the bottom plate 120 and the enclosing wall 121. The inner element 11 is received in the receiving space 122 and is located on a top surface of the bottom plate 120 of the outer element 12. The outer element 12 is directly formed on the inner element 11 by an integrated molding process so that the outer element 12 is integrally molded with the inner element 11. The details of the molding process for the footpad 10 will be described hereinafter.

Still referring to FIGS. 2-5, in the embodiment illustrated, the inner element 11 forms a plurality of positioning holes 112 extending completely through top and the bottom surfaces of the inner element 11 and a plurality of side holes 113 formed in a circumferential side wall thereof. During the integrated molding process, a plurality of positioning posts 123 are formed on the top surface of the bottom plate 120 of the outer element 12 as the molding material is filled into the positioning holes 112 of the inner element 11, and similarly, a plurality of positioning ribs 124 are formed on an inner surface of the enclosing wall 121 as the molding material is filled into the receiving space 122 and the side holes 113 of the inner element 11. Top ends of the positioning posts 123 are made substantially flush with a top surface of the inner element 11 when the positioning posts 123 are filled into the positioning holes 112. Moreover, the outer element 12 has a dented area 125 formed on a bottom surface of the bottom plate 120 and, if desired, forming thereon anti-slip patterns or lines to improve the friction of the bottom surface of the footpad 10. It is understood that the dented area 125 and the anti-slip lines can be of other shapes/configurations and arrangements.

Also referring to FIGS. 6-9, to mount the footpad 10 to the notebook computer 1, the following steps are performed sequentially:

Firstly, an adhesive layer 15 is coated on the top surface of the footpad 10, as shown in FIGS. 6 and 7.

Secondly, the securing posts 110 of the footpad 10 are fit into the securing holes 14 defined in the bottom surface 13 of the notebook computer 1. Top free ends or heads of the securing posts 110 protrude beyond the securing holes 14 and partially into an inner surface 16 of the notebook computer 1, as shown in FIG. 8. The footpad 10 is thus temporarily fixed to the bottom surface 13 of the notebook computer 1 by the adhesion force of the adhesive layer 15 in order to carry out the subsequent steps of the mounting process.

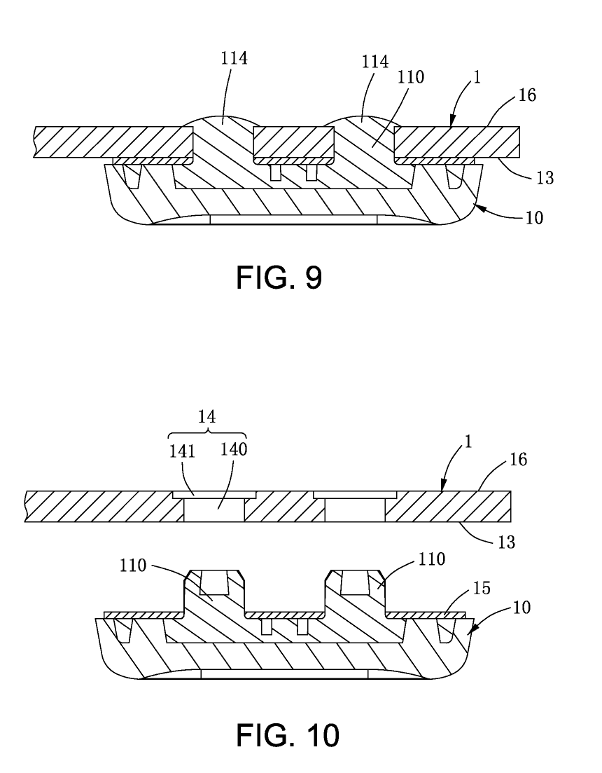

Finally, a hot-melting step is carried out on the heads of the securing posts 8. The head of each securing post 110, which extends beyond the corresponding securing hole 14, is heated and melted and becomes an expanded head, which effectively prevents the securing post 8 from separating from the securing hole 14, as shown in FIG. 9. The footpad 10 is firmly secured to the bottom surface 13 of the notebook computer 1 by the above process and thus the problem of separation occurring in the conventional footpad can be overcome.

In a preferred embodiment of the present invention, as shown in FIGS. 7-9, the securing hole 14 is a cylindrical hole receiving the securing post 110 therein. The head of the securing post 110 is subjected to hot-melting to become an expanded, mushroom-like head 114 protruding beyond the inner surface 16 of the notebook computer 1.

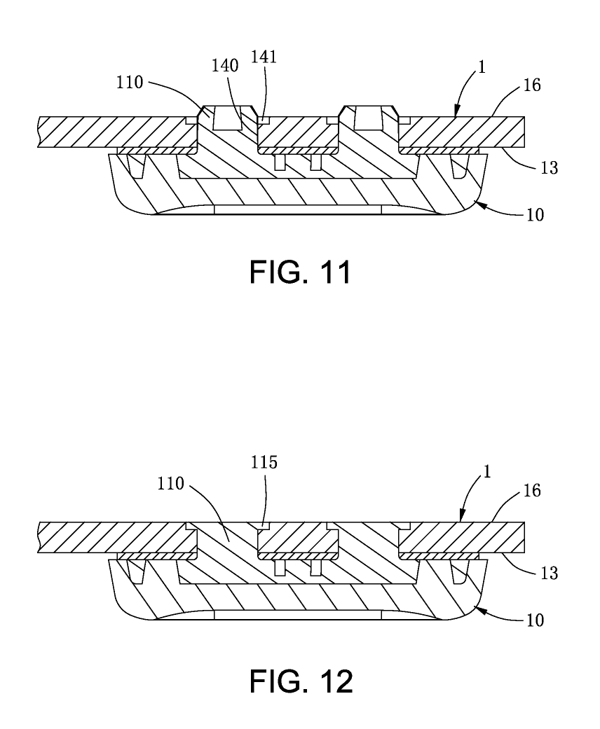

In another embodiment of the present invention, as shown in FIGS. 10-12, the securing hole 14 includes a cylindrical hole 140 and a counter bore 141 the diameter of which is larger than that of the cylindrical hole 140. The head of the securing post 110 extending into the securing hole 14, after being subjected to the hot-melting process, becomes a securing head 115 received and retained in the counter bore 141 without substantially protruding beyond the inner surface 16 of the notebook computer 1, whereby the inner space of the notebook computer 1 can be saved for arranging more components (not shown) therein.

The footpad 10 has an integrated structure because the inner element 11 of plastic material is integrally molded with the outer element 12 of rubber material by the integrated molding process. The footpad 10 of the present invention has an extended lifespan and can improve the operational safety of the notebook computer 1.

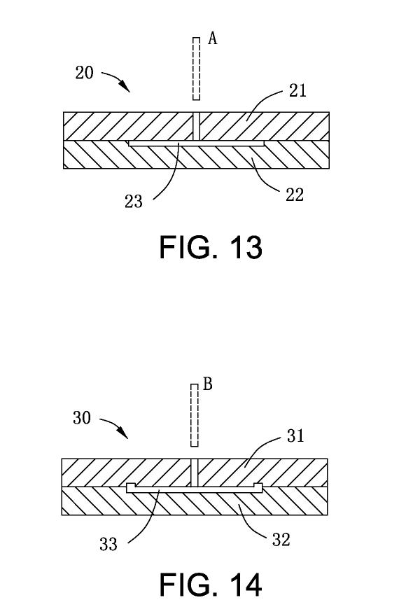

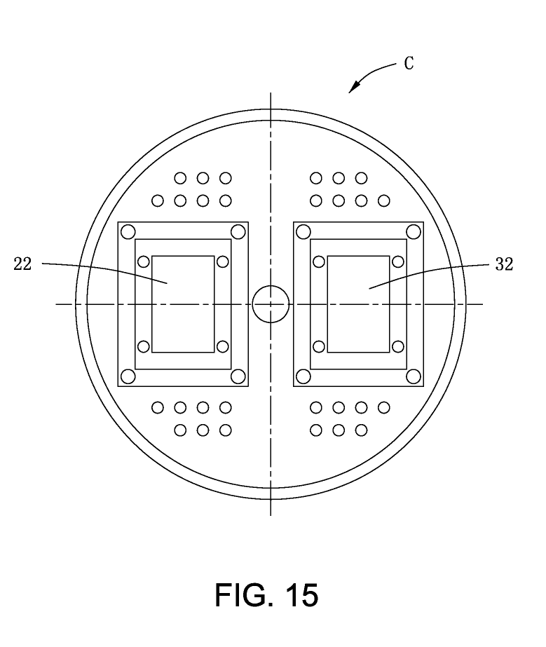

Also referring to FIGS. 13-15, to mold the footpad 10 with two different materials, namely plastic and rubber in the embodiment illustrated, an injection molding machine including a plastic injection molding assembly 20 and a rubber injection molding assembly 30 is employed.

The injection molding machine has a rotation table C on which the plastic and rubber injection molding assemblies 20, 30 are arranged. A plastic injection pipe A used to inject the plastic material and a rubber injection pipe B used to inject the rubber material are respectively provided for the plastic and rubber injection molding assemblies 20, 30. The plastic injection molding assembly 20 consists of a female mold 21 and a male mold 22. In the embodiment illustrated, the female mold 21 is arranged right below the plastic injection pipe A; the male mold 22 is set beneath the female mold 21 to thereby define a mold cavity 23 therebetween. Accordingly, the plastic material is supplied and injected through the plastic injection pipe A into the mold cavity 23 via an inlet of the plastic injection molding assembly 20. The rubber injection mold assembly 30 also consists of a female mold 31 and a male mold 32. The female mold 31 is arranged right below the rubber injection pipe B; the male mold 32 is set beneath the female mold 31 to thereby define a mold cavity 33 therebetween. Accordingly, the rubber material is supplied and injected through the plastic injection pipe B into the mold cavity 33 via an inlet of the rubber injection molding assembly 30.

With the installation described above, there are two injection molding, namely the plastic injection molding assembly 20 and the rubber injection molding assembly 30, together with two injection pipes, namely the plastic injection pipe A and the rubber injection pine B, are set on the rotation table C of the injection molding machine. Then, the following steps can be performed sequentially:

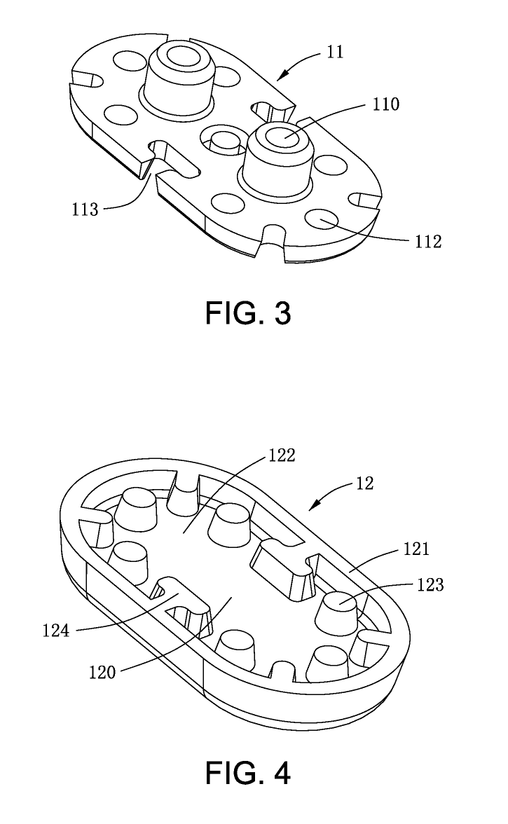

(1) A first injection molding operation is carried out by means of the plastic injection pipe A, which injects the plastic material into the mold cavity 23 of the plastic injection molding assembly 20 to form a semi-finished product, namely, the inner element 11 (shown in FIG. 3). In detail, the plastic injection pipe A has a nozzle that is forced against the inlet of the plastic injection molding assembly 20 by for example hydraulic driving, and molten plastic material in the plastic injection pipe A is then driven into the mold cavity 23 of the plastic injection molding assembly 20. The kind and amount of the plastic material, and the injection time and pressure for the injection pipe A can be adjusted according to the final product configuration and the customer requirements. After the plastic injection is completed, the nozzle of the plastic injection pipe A is separated from the inlet of the plastic injection molding assembly 20. The plastic material injected in the mold cavity 23 is then cooled and solidified to form the inner element 11 of the footpad 10.

(2) Then, the rotation table C is then rotated for example 180 degrees, whereby the male mold 22 of the plastic injection molding assembly 20 with the semi-finished product therein and the male mold 32 of the rubber injection molding assembly 30 are simultaneously moved to exchange their positions with each other. However, the original positions of the two injection pipes A and B and those of the female molds 21, 31 of the plastic and rubber injection molding assemblies 20, 30, are maintained. As a result, the male mold 22 with the semi-finished product therein is now located under the rubber injection pipe B and the female mold 31; and the male mold 32 is now located under the plastic injection pipe A and the female mold 21.

Thereafter, a second injection molding operation is performed with the rubber injection pipe B, which injects the rubber material into the mold cavity 23 where the semi-finished product stays. Thus, the rubber outer element 12 is further molded on the plastic inner element 11, whereby an integrated injection-molded final product, that is the footpad 10, is obtained after cooling and solidifying of the rubber material. Since the steps of the second injection molding operation are substantially the same as those of the first injection molding operation, a detailed description thereof is thus omitted herein. In the course of the performance of the second injection molding operation, a third injection molding operation is further simultaneously performed by means of the plastic injection pipe A again to inject the plastic material into the empty mold cavity 33 defined between the male mold 32 and the female mold 21. Thus, a second semi-finished product, namely a second inner element 11 for the footpad 10, is further formed.

(4) Then, the mold is open for removing the finished product formed in the second injection molding operation from the mold cavity 23. The finished product is ejected out of the mold cavity by an ejection pin (not shown) on the injection molding machine, and is then picked up by a mechanical arm.

As described above, in step (3), a first finished product, such as the footpad 10, and a second semi-finished product, such as the inner element 11, are simultaneously formed in the corresponding mold cavities 23 and 33 by the respective second and third injection molding operations. After the first finished product is removed from the mold cavity, steps (2) to (4) are repeated to form the second semi-finished product into a second finished product by the rubber injection molding operation, and to form a third semi-finished product by the plastic injection molding operation. Thus, by performing continuously and repeatedly the molding operations, a large amount of finished products can be obtained, whereby productivity is significantly increased and the finished product quality is also maintained. Further, because the inner element 11 and the outer element 12 of the final footpad 10 are integrally injection molded, the notebook computer having the footpad 10 is safe and reliable.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A footpad adapted to mount to a bottom surface of an external device, comprising:
an inner element made of a first material having a first friction coefficient, the inner element having a top surface on which a securing post is formed for insertion into a securing hole defined in the bottom surface of an external device; and
an outer element made of a second mouldable material having a second friction coefficient greater than the first friction coefficient and integrally molded on the inner element, the outer element comprising a bottom plate having a top surface on which the inner element is positioned.

2. The footpad as claimed in claim 1, wherein the outer element comprises an enclosing wall extending upward from a circumference of the bottom plate and defining a receiving space with the bottom plate to receive the inner element therein.

3. The footpad as claimed in claim 1, wherein the inner element has a bottom surface opposite to the top surface and the inner element forms a positioning hole extending through the top and bottom surfaces thereof, and wherein the outer element forms a positioning post extending from the top surface of the bottom plate thereof and further extending into the positioning hole of the inner element in such a way that a free top end of the positioning post is substantially flush with the top surface of the inner element.

4. The footpad as claimed in claim 1, wherein the inner element has a circumferential sidewall forming therein a side hole and wherein the outer element forms a rib extending into the side hole of the inner element.

5. The footpad as claimed in claim 1, wherein the outer element comprises anti-slip patterns formed on a bottom surface of the bottom plate thereof.

6. A notebook computer comprising:
a bottom in which a securing hole is defined; and
a footpad comprising:
an inner element made of a first material having a first friction coefficient, the inner element having a top surface on which a securing post formed and received in the securing hole of the bottom of the notebook computer; and
an outer element made of a second, mouldable material having a second friction coefficient greater than the first friction coefficient and integrally molded on the inner element, the outer element comprising a bottom plate having a top surface on which the inner element is positioned.

7. The notebook computer as claimed in claim 6, wherein the securing hole of the notebook computer comprises a cylindrical through hole, which receives the securing post of the footpad in such a way that a head of the securing post is expanded and projecting beyond an inner surface of the bottom of the notebook computer.

8. The notebook computer as claimed in claim 6, wherein the securing hole of the notebook computer comprises a cylindrical hole segment and a counter bore segment in communication with the cylindrical hole segment and having an inner diameter larger than an inner diameter of the cylindrical hole segment, the securing post of the footpad being received in the cylindrical hole so that a head of the securing post is expanded and received and retained in the counter bore.

9. The notebook computer as claimed in claim 6, wherein the outer element comprises an enclosing wall extending upward from a circumference of the bottom plate and defining a receiving space with the bottom plate to receive the inner element therein.

10. The notebook computer as claimed in claim 6, wherein the inner element has a bottom surface opposite to the top surface and the inner element forms a positioning hole extending through the top and bottom surfaces thereof, and wherein the outer element forms a positioning post extending from the top surface of the bottom plate thereof and further extending into the positioning hole of the inner element in such a way that a free top end of the position post is substantially flush with the top surface of the inner element.

11. The notebook computer as claimed in claim 6, wherein the inner element has a circumferential sidewall forming therein a side hole and wherein the outer element forms a rib extending into the side hole of the inner element.

12. The notebook computer as claimed in claim 6, wherein the outer element comprises anti-slip patterns formed on a bottom surface of the bottom plate thereof.
